(19) United States
(12) Patent Application Publication
(10) Pub. No.: US 2005/0259458 A1
(43) Pub. Date: Nov. 24, 2005

(54) Method and system of encrypting/decrypting data stored in one or more storage devices

(76) Inventors: Viresh Rustagi, Sunnyvale, CA (US); Chris Wilson, Sunnyvale, CA (US); Zhaoxiang (Randy) Pan, Union City, CA (US); John Stuart, Los Altos, CA (US)

Correspondence Address: MCANDREWS HELD & MALLOY, LTD, 500 WEST MADISON STREET, SUITE 3400, CHICAGO, IL, 60661, US

(21) Appl. No.: 11/086,189

(22) Filed: Mar. 22, 2005

Related U.S. Application Data
(60) Provisional application No. 60/573,285, filed on May 21, 2004.

(51) Int. Cl. G11C 5/06

(52) U.S. Cl. 365/63

(57) ABSTRACT

Various aspects of the invention provide for one or more methods and systems of encrypting and storing data into one or more data storage devices. Aspects of the invention provide a system and method of preventing unauthorized use of data stored in the data storage device. In one embodiment, the one or more data storage devices comprises one or more hard disk drives. In one or more embodiments, the one or more methods comprises executing a software that generates one or more device drivers. The one or more methods utilizes the one or more device drivers to encrypt data prior to storing into one or more data storage devices, or to decrypt encrypted data stored in one or more data storage devices. In one or more embodiments, the one or more systems comprises one or more memories, software resident in the one or more memories, and a processor.

### CROSS-REFERENCE TO RELATED APPLICATIONS/INCORPORATION BY REFERENCE

This application makes reference to and claims priority from U.S. Provisional Patent Application Ser. No. 60/573,285, entitled “METHOD AND SYSTEM OF ENCRYPTING/DECRYPTING DATA STORED IN A STOAGE DEVICE”, filed on May 21, 2004, the complete subject matter of which is incorporated herein by reference in its entirety.

This application makes reference to:
U.S. application Ser. No. 11/049,905 (Attorney Docket No. 15673US02) filed Feb. 3, 2005; and
U.S. application Ser. No. ______ (Attorney Docket No. 15675US03) filed Mar. 22, 2005.

The above stated applications are hereby incorporated herein by reference in their entireties.

### FEDERALLY SPONSORED RESEARCH OR DEVELOPMENT

[Not Applicable]

### MICROFICHE/COPYRIGHT REFERENCE

[Not Applicable]

### BACKGROUND OF THE INVENTION

A data processing or computing device may contain one or more data storage devices. These data storage devices, such as one or more hard disk drives, may often contain sensitive or confidential data. When an unauthorized user gains control of a data processing device, he often has easy access to the contents of a hard disk drive. The data may be easily read using any one of a number of applications. Further, the data may be easily copied and stolen by way of portable media.

The limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

Various aspects of the invention provide for a method and system of encrypting and decrypting data stored in a data storage device. Aspects of the invention provide a system and method of preventing unauthorized access of the data stored in the data storage device. In one embodiment, the data storage device comprises one or more hard disk drives.

In one embodiment, a method of preventing unauthorized use of data that is stored in one or more data storage devices comprises executing a software that generates one or more device drivers and utilizing the one or more device drivers to encrypt the data.

In one embodiment, a method of storing encrypted data into one or more data storage devices comprises generating a first signal from a file system, transmitting the first signal to a first device driver, generating a second signal from the first device driver resulting from receiving the first signal, transmitting the second signal to a second device driver, encrypting the data to generate encrypted data, storing the encrypted data into a buffer, generating a third signal to the first device driver that indicates encryption has been performed, generating a fourth signal to a third device driver from the first device driver, wherein the third device driver provides control for writing data into the one or more data storage devices, and writing the encrypted data from the buffer into the one or more data storage devices.

In one embodiment, a method of decrypting and reading encrypted data stored in one or more data storage devices comprises generating a first signal from a file system, transmitting the first signal to a first device driver, generating a second signal from the first device driver, transmitting the second signal from the first device driver to a second device driver, wherein the second device driver provides control for reading data from the one or more data storage devices, reading data stored in the one or more data storage devices, generating a second signal from a second device driver to the first device driver indicating that the data is read from the one or more data storage devices, generating a third signal from the first device driver to a third device driver causing the data to be decrypted from the one or more data storage devices, and storing the decrypted data into a buffer.

In one embodiment, a system for securely storing encrypted data using one or more data storage devices comprises one or more memories, a software resident in the one or more memories, and a processor that executes the software resident in the one or more memories.

These and other advantages, aspects, and novel features of the present invention, as well as details of illustrated embodiments, thereof, will be more fully understood from the following description and drawings.

### BRIEF DESCRIPTION OF THE DRAWINGS

FIG. 1 illustrates a block diagram of a typical system incorporating the use of a storage device capable of being networked with one or more computing devices in accordance with an embodiment of the invention.

FIG. 2 is a block diagram of a network attached storage device (NAS) capable of encrypting/decrypting data, in accordance with an embodiment of the invention.

FIG. 3 is a block diagram of an integrated circuit chip employing an encryption/decryption circuitry, in accordance with an embodiment of the invention.

FIG. 4 is a system block diagram illustrating an exemplary embodiment of a system implementing the encryption/decryption of data, in accordance with an embodiment of the invention.

FIG. 5 provides an exemplary illustration of a software system using one or more tasks, messages, commands, or signals generated by the software system when writing encrypted data stored in one or more storage devices of the exemplary NAS, in accordance with an embodiment of the invention.

FIG. 6 provides an exemplary illustration of a software system using one or more tasks, messages, commands, or signals generated by the software system when reading encrypted data stored in one or more storage devices of the exemplary NAS, in accordance with an embodiment of the invention.

FIG. 7 is an operational flow diagram illustrating a generation of an encryption key or digest used by an encryption/decryption circuitry or hardware, allowing data to be encrypted into a storage device of an exemplary NAS, in accordance with an embodiment of the invention.

FIG. 8 is an operational flow diagram illustrating a generation of an encryption key or digest used by an encryption/decryption circuitry or hardware, allowing data to be encrypted into a storage device of an exemplary NAS, in accordance with an embodiment of the invention.

### DETAILED DESCRIPTION OF THE INVENTION

Various aspects of the invention provide for a method and system of encrypting and decrypting data stored in a data storage device. Aspects of the invention provide a system and method of preventing unauthorized access of the data stored in the data storage device. In one embodiment, the data storage device comprises one or more hard disk drives. In one embodiment, the encryption or decryption is performed on a per disk pool or per data pool basis. Portions or sectors of one or more hard disk drives may be collectively pooled in order to create one or more data pools. The pools may be considered logical drives. In one or more embodiments, the one or more hard drives are first re-partitioned and then collectively pooled in order to most efficiently utilize the hard disk drive space provided by the one or more hard disk drives. The hard disk drives may be grouped together to provide increased data storage capacity or to provide data mirroring or data striping. In one embodiment, the grouped or linked hard disk drives are physically contained within a single data storage device. In one embodiment, the data storage device is networked in a local area network, for example, to provide a storage facility for any number of data processing or computing devices. The data processing or computing devices may comprise one or more computers, for example. Additional aspects of the invention provide shared access to one or more data pools created in the storage device, using share names. In one or more embodiments hereinafter, the aforementioned networked data storage device may be termed a network attached storage device (NAS).

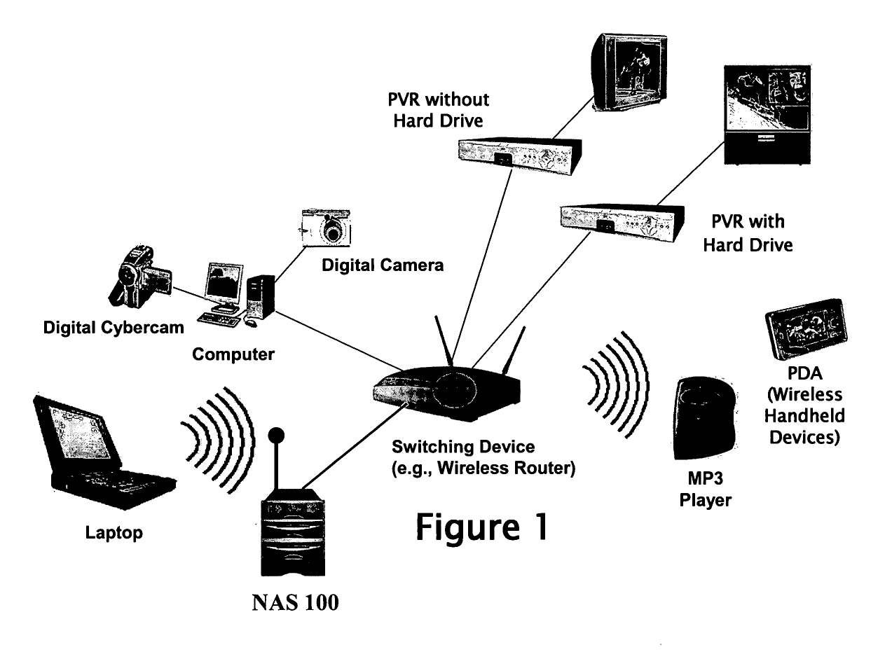

FIG. 1 illustrates a block diagram of a typical system incorporating the use of a storage device capable of being networked (e.g., a NAS) with one or more computing devices in accordance with an embodiment of the invention. The NAS 100 provides data storage for one or more data processing devices. The NAS 100 may be communicatively coupled to one or more data processing or computing devices. As shown, the NAS 100 may be communicatively coupled to a laptop by way of a wireless link. In the exemplary system illustrated in FIG. 1, a switching device provides connectivity of the NAS 100 to the one or more data processing devices. In this embodiment, the NAS 100 is connected to the switching device by way of a wireline connection. The wireline connection may comprise an Ethernet connection, for example. The NAS 100 may also communicate wirelessly as shown. The type of wireless communication may comprise 802.11x, Bluetooth, circuit switched cellular, or the like. The switching device is capable of providing connectivity using wireless or wireline communications. For example, a wireless router may utilize any one of the following wireless or wireline data communications protocols: 10/100 Ethernet, gigabit Ethernet, 802.11x, Bluetooth, and the like. The one or more data processing devices comprises devices such as a digital cybercam, digital camera, MP3 player, PDA, and one or more personal video recorders (PVRs). As illustrated, the PVR may be equipped with or without a hard disk drive. In one embodiment, the PVR may be referred to as a set-top-box (STB) that incorporates personal video recorder capabilities. In one embodiment, the PVR may be referred to as a PVR-STB. The PVRs illustrated, are connected to a television or a monitor capable of playing multimedia content to a home user. In one embodiment, use of the NAS 100 provides a centralized storage device for multimedia content received by the one or more PVRS. As a consequence of storing content in a NAS 100, PVRs lacking a storage facility, such as a hard disk drive, may store any data it receives into the NAS 100. Further, any data stored by other data processing devices, including PVRs, may be easily accessed and viewed by any of the one or more data processing devices. For example, a PVR without hard drive may access multimedia content originally stored into the NAS 100 by a PVR with hard drive, and vice-versa. As a result, the NAS 100 facilitates sharing of data among the one or more data processing devices. Since it provides a remote storage mechanism, the NAS 100 may be considered a “virtual storage device” by the one or more data processing devices. The NAS 100 is configured such that its storage capacity may be easily expanded. In one embodiment, the NAS 100 may accept additional hard disk drives. In an alternate embodiment, the NAS may be configured for expansion, by connecting one or more additional NAS' to the existing NAS. The NAS may be linked together by one or more connectors and wires. As such, the NAS 100 provides an easily scalable and flexible storage mechanism that accommodates for future data storage growth. In addition, the NAS 100 is quite suitable for providing data mirroring and data striping capabilities.

When the NAS is first introduced to the exemplary switching device shown in FIG. 1, one or more of its parameters may be setup as part of an initialization process. In one embodiment, the parameters setup during the initialization process comprises the NAS' time, date, and time zone. The NAS, for example, may utilize the computer illustrated in FIG. 1 as a reference source in setting up its time, date, and time zone. It is contemplated that the NAS may utilize any one of the other data processing devices (e.g., digital cybercam, digital camera, PVR without hard drive, PVR with hard drive, MP3 player, or PDA) shown in FIG. 1 as a reference source in the setup process.

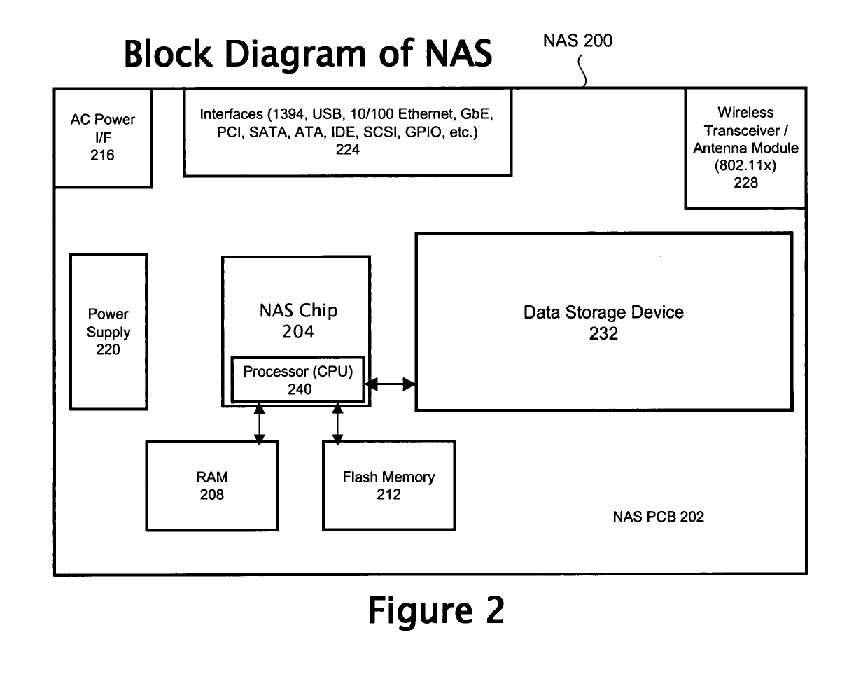

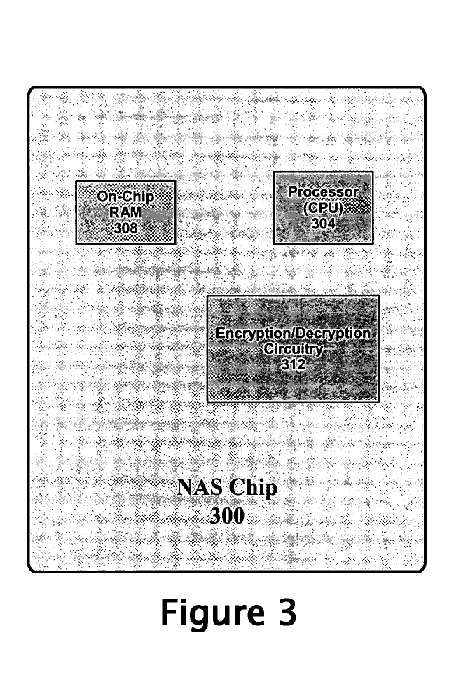

In one embodiment, the NAS setup process occurs after the NAS is physically connected to a network and recognized by an operating system such as a Microsoft Windows or Linux operating system. The following FIGS. 2 and 3 illustrate an embodiment of a NAS' system architecture and NAS chip (integrated circuit), respectively, in accordance with embodiments of the invention.

FIG. 2 is a block diagram of a network attached storage device (NAS) capable of encrypting/decrypting data, in accordance with an embodiment of the invention. The NAS 200 comprises a printed circuit board (NAS PCB) 202 containing one or more components. The one or more components are electrically connected by way of the printed circuit board (PCB) 202. The one or more components comprises a NAS chip 204, a random access memory (RAM) 208, a flash memory 212, an AC power interface 216, a power supply 220, an interface block 224, a wireless transceiver/antenna module 228, and a data storage device 232. In one embodiment, the data storage device 232 comprises one or more hard disk drives. In another embodiment, the storage device 232 may comprise one or more optical drives, CD drives, DVD drives, compact memory (e.g., flash), or tape drives. The interface block 224 may comprise one or more of the following interfaces: IEEE 1394, USB, 10/100 Ethernet, gigabit Ethernet, PCI, SATA, ATA, IDE, SCSI, GPIO, etc. The one or more interfaces of the interface block 224 may be used for communicating to one or more data processing or computing devices in a network. The wireless transceiver/antenna module 228 may comprise an attachable module or mini-PCI card that may be optionally connected or attached to the NAS' printed circuit board 202. The wireless transceiver/antenna module 228 may also be used to communicate with one or more data processing or computing devices in a network. The storage device 232 may comprise any number of hard drives depending on the design of the NAS 200. The printed circuit board 202 may be configured to accommodate an appropriate number of hard drives. In one embodiment, the number of hard drives utilized may depend on the type of mirroring or data striping (i.e., RAID) provided by the NAS 200. The NAS chip 204 may comprise an integrated circuit chip incorporating a processor or central processing unit (CPU) 240, as well as an encryption/decryption circuitry (as will be shown in FIG. 3). The random access memory (RAM) 208 may comprise an SDRAM. As illustrated, the CPU 240 may communicate or interact with the RAM 208 and/or flash memory 212.

FIG. 3 is a block diagram of an integrated circuit chip employing an encryption/decryption circuitry, in accordance with an embodiment of the invention. The NAS chip 300 is an integrated circuit implementing one or more functions, which is mounted on the previously described NAS PCB. The NAS chip 300 provides one or more functions that allow the NAS to properly operate. The NAS chip 300 comprises a central processing unit (CPU) 304 (240, FIG. 2), an on-chip random access memory (RAM) 308 and an encryption/decryption circuitry 312. The NAS chip 300 may communicate and/or connect to the one or more components described in reference to FIG. 2. The CPU 304 may interact with the flash memory or random access memory that resides on the printed circuit board, previously described in reference to FIG. 2. The CPU 304 may execute a compilation of software residing in the flash memory. The software may comprise a Linux loadable module that is stored or downloaded into the flash memory by a user.

In one embodiment, the processor 240 within the NAS chip (204 or 300) executes the software residing within the RAM 208 when the NAS is booted up or powered up. In one embodiment, execution of the software or firmware generates one or more user interfaces, such as a graphical user interface (GUI), allowing a user to input one or more passwords that permits a user to access data in the data storage device. The user either encrypts data when writing to the storage device or decrypts data when reading from the storage device. In one embodiment, the storage device comprises one or more hard disk drives.

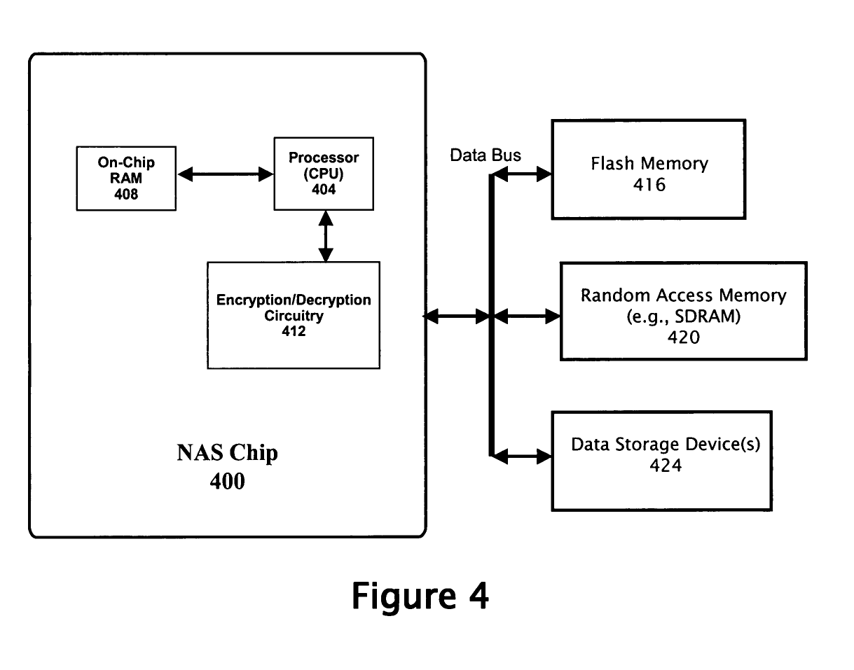

FIG. 4 is a system block diagram illustrating an exemplary embodiment of a system implementing the encryption/decryption of data, in accordance with an embodiment of the invention. The system may comprise the network attached storage device (NAS) previously mentioned. The system block diagram comprises one or more components previously described in relation to the printed circuit board of FIG. 2 and includes the NAS chip described in FIG. 3. As shown, the system comprises a NAS chip 400, a flash memory 416, a random access memory (RAM) 420, and one or more data storage devices 424. The flash memory 416 may comprise a non-volatile memory capable of storing an exemplary Linux loadable module. It is contemplated that other types of loadable modules may be stored within the flash memory 416. The RAM 420 may comprise an SDRAM. The data storage devices 424 may comprise one or more hard disk drives. The NAS chip 400 comprises a processor (CPU) 404, an on-chip random access memory (RAM) 408, and an encryption/decryption circuitry 412. The on-chip random access memory (RAM) 408 may be used by the CPU 404 for processing certain data. Although the on-chip RAM 408 may comprise any type of memory, in one representative embodiment, the on-chip RAM 408 may comprise a cache memory. The CPU 404 may control encryption operations performed by the encryption/decryption circuitry 412. An encryption key is stored in the RAM 420 for use by the encryption/decryption circuitry 412 when encrypting data. In one embodiment, the Linux loadable module stored in the flash memory 416 may be loaded into the RAM 420. The CPU 404 may execute the Linux loadable module stored in RAM 420 allowing a streaming encryption device driver to be implemented. The streaming encryption device driver provides one or more generic block device driver functions. In one embodiment, these functions may comprise open, release, and ioctl. The streaming encryption device driver may act as a driver for one or more data storage devices 424. In one embodiment, a total of 256 data storage devices 424 may be driven by the streaming encryption device driver. The NAS printed circuit board (PCB), as referenced in FIG. 2, may employ a data bus (as shown in FIG. 4) to efficiently transmit data between the different components shown.

The encryption/decryption circuitry 412 comprises any circuitry or hardware used to perform encryption or decryption of the data stored in the one or more data storage devices. The encryption/decryption circuitry 412 functions to encrypt data being written into one or more storage devices. Similarly, the encryption/decryption circuitry 412 functions to decrypt data read from the one or more storage devices. In one embodiment, the encryption/decryption circuitry 412 is capable of encrypting or decrypting data stored in up to 256 data storage devices. In one embodiment, the encryption/decryption circuitry 412 utilizes one or more encryption keys, used to encrypt or decrypt data stored in the one or more data storage devices. The encryption key used by the encryption/decryption circuitry 412 may be a function of one or more passwords or codewords input by a user. The encryption/decryption circuitry 412 may implement one or more encryption/decryption algorithms using the one or more encryption keys. In one embodiment, the encryption/decryption circuitry 412 employs the Advanced Encryption Standard (AES) algorithm. In one or more other embodiments, the encryption/decryption circuitry 412 may utilize the Data Encryption Standard (DES) or triple DES (3DES) algorithms to encrypt data stored in the one or more data storage devices. The password string utilized by the streaming encryption device driver may be any length. However, in one embodiment, the password length comprises 255 characters. In one embodiment, a user provides this password string, by way of a user interface, when executing the Linux loadable module stored in the RAM 420. It is contemplated that other mechanisms, not limited to using the user interface, may be used to input the password by the user.

In one embodiment, a MD5 hash function is applied on the password, generating a 128-bit digest. The 128-bit digest is used as the encryption (or decryption) key, by the encryption/decryption circuitry 412. In this embodiment, two different password strings, provided by a user, will theoretically never produce the same 128-bit digest value.

In another embodiment, the MD5 hash function is applied using one or more MD-5 hash keys using a single password. As discussed previously, the password may be input by a user using a user interface. In one embodiment, the one or more MD-5 hash keys are stored in the random access memory 420. When using two MD-5 hash keys, two unique 128-bit digest values are obtained. These two 128-bit digests may be concatenated to form a 256-bit digest. The encryption/decryption circuitry may use the 256-bit digest or encryption/decryption key to encrypt or decrypt data. In one embodiment, the data to be encrypted/decrypted may comprise any data stored in a data pool of the one or more data storage devices. The data pool, may comprise portions of one or more hard disk drives in the one or more data storage devices. The data pool, for example, may comprise information concerning the file system of the data pool. In one embodiment, the data encrypted may include any metadata that characterizes the data stored in a data pool. The metadata may store information related to the files in the data pool, such as the number of files, the number of blocks, and the date a file is created, for example.

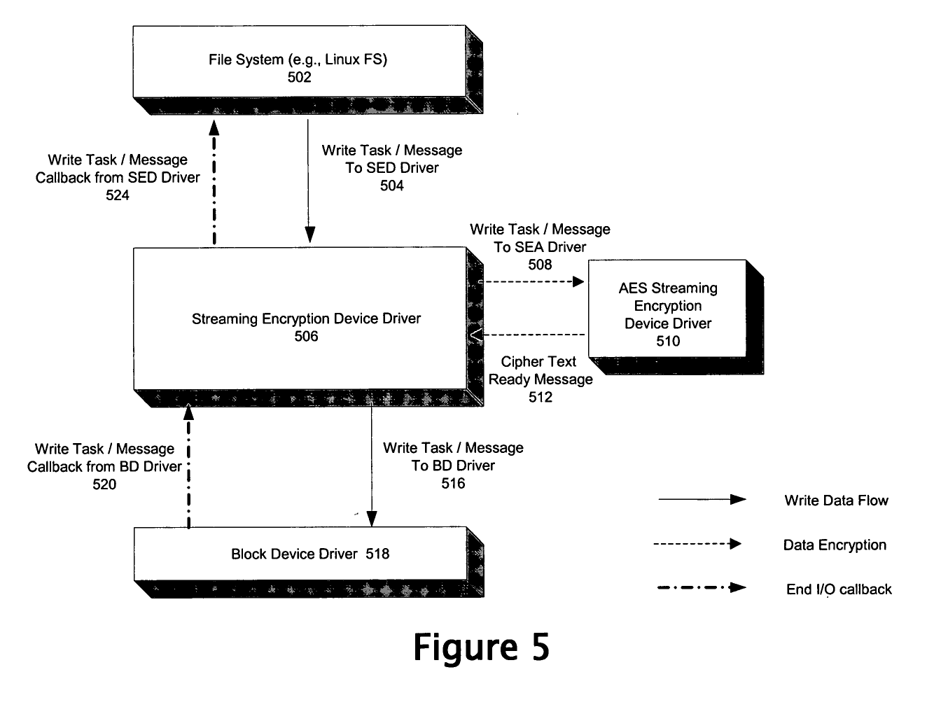

FIG. 5 provides an exemplary illustration of a software system using one or more tasks, messages, commands, or signals generated by the software system when writing encrypted data stored in one or more storage devices of the exemplary NAS, in accordance with an embodiment of the invention. The software system or software based system comprises one or more software drivers that communicate by way of one or more tasks, messages, commands, or signals. The software system is invoked by executing the Linux loadable module stored in memory. The memory may comprise the random access memory as described in relation to FIG. 4. In one embodiment, the software system comprises a file system 502 such as a Linux file system (e.g., a Reiser file system) and a number of device drivers 506, 510, 518. The file system 502 may communicate with one or more device drivers in different layers of a software stack. In one embodiment, the device drivers may comprise the following exemplary drivers: a streaming encryption device driver 506, an AES streaming encryption device driver 510, and a block device driver 518. A write operation commences when the file system generates a write task/message 504 to the streaming encryption device driver 506. As a consequence of the write task/message 504 to the streaming encryption device driver 504, a write task/message 508 to the AES streaming encryption device driver 510 is generated and transmitted to the AES encryption device driver 510. The write task/message to an AES streaming encryption device driver 510 is used to facilitate encryption of plain text from a plain text buffer. The encrypted data is subsequently stored into a cipher text buffer. Subsequently, a cipher text ready message 512 may be generated by the AES streaming encryption device driver 510, to indicate that data encryption has been successfully performed. In response, the streaming encryption device driver 506 generates a write task/message 516 to the block device driver 518. As a result, the block device driver 518 facilitates the transfer of encrypted data into a designated storage device, such as a hard disk drive. After the encrypted data is stored into the designated storage device (such as a hard disk drive), the block device driver 518 generates a write task/message callback 520. The write task/message callback 520 facilitates the streaming encryption device driver 506 to generate a write task/message callback 524. The write task/message callback 524 from the streaming encryption device driver 506 is used to notify the file system 502 that the data write operation has been successfully completed. The previously described random access memory (RAM) may be used for implementing the plain text and cipher text buffers.

In one embodiment, a Linux file system writes data using one or more pages, wherein each page is typically 4096 bytes. In one embodiment, each data transfer operation for a block device driver occurs over a group of adjacent sectors of an exemplary hard disk drive. In one embodiment, the size of a sector is 512 bytes. In one embodiment, the minimum data write size is one sector.

In one embodiment, the streaming encryption device driver 506 encodes data on a per sector basis. When a write request arrives at a streaming encryption device driver 506, the streaming encryption device driver 506 allocates a buffer (e.g., from RAM) capable of storing a page of data (4096 bytes). Then, the streaming encryption device driver 506 utilizes a security reference library (SRL) that facilitates a set up the AES streaming encryption device driver 510, so as to encode data into the buffer.

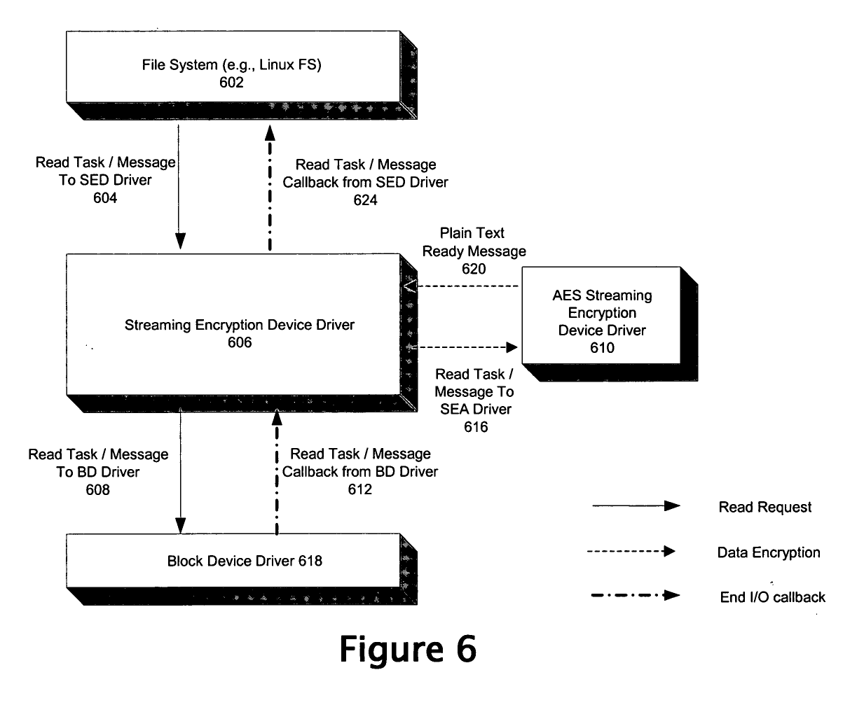

FIG. 6 provides an exemplary illustration of a software system using one or more tasks, messages, commands, or signals generated by the software system when reading encrypting data stored in one or more storage devices of the exemplary NAS, in accordance with an embodiment of the invention. The software system or software based system comprises one or more software drivers that communicate by way of one or more tasks, messages, commands, or signals. The software system is invoked by executing the Linux loadable module stored in memory. The memory may comprise the random access memory as described in relation to FIG. 4. In one embodiment, the software system comprises a file system 602 such as a Linux file system (e.g., a Reiser file system) and a number of device drivers 606, 610, 618. The file system 602 may communicate with device drivers in different layers of a software stack. The device drivers comprise the following exemplary drivers: a streaming encryption device driver 606, an AES streaming encryption device driver 610, and a block device driver 618. A read operation commences when the file system generates a read task/message 604 to the streaming encryption device driver 606. As a consequence of the read task/message 608 to the block device driver 618, a read task/message callback 612 from the block device driver 618 is generated and transmitted to the streaming encryption device driver 606. The read task/message 608 initiates reading of the encrypted data from the one or more storage devices of the exemplary NAS. As a result, a read task/message 616 to the AES streaming encryption device driver 610 is generated from the streaming encryption device driver 606. The read task/message 616 to the AES streaming encryption device driver 610 is used to facilitate decryption of cipher text from a cipher text buffer. The decrypted data is subsequently stored into a plain text buffer. Subsequently, a plain text ready message 620 may be generated by the AES streaming encryption device driver 610, to indicate that data decryption has been successfully performed. In response, the streaming encryption device driver 606 generates a read task/message callback 624 to the file system 602, so as to notify the file system 602 that the data read operation has been successfully completed.

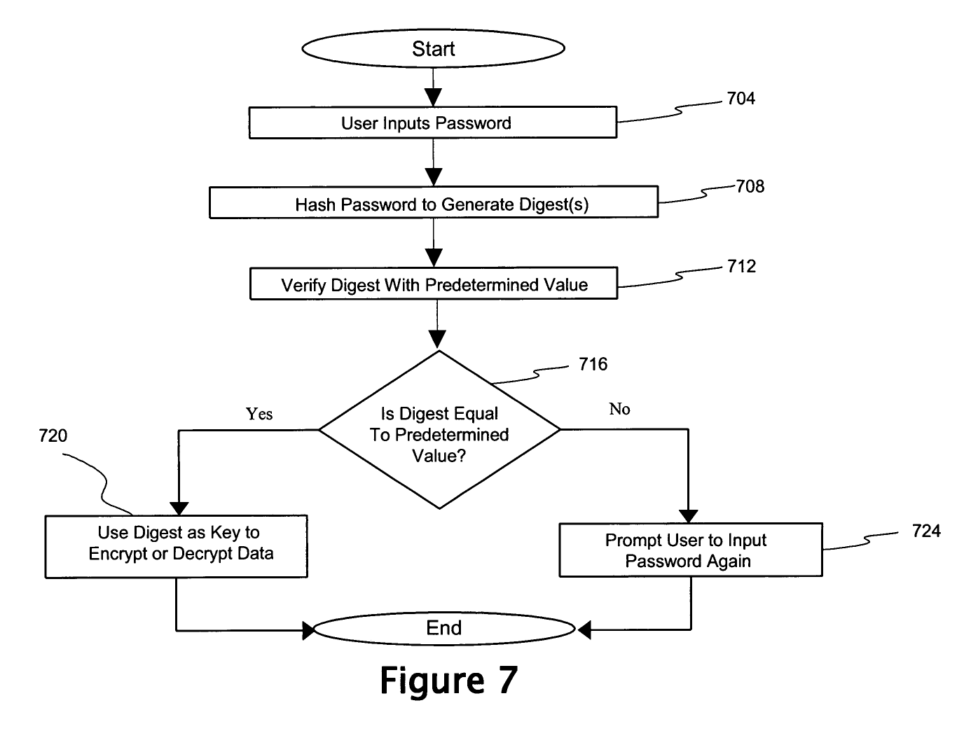

FIG. 7 is an operational flow diagram illustrating a generation of an encryption key or digest to be used by an encryption/decryption circuitry or hardware, allowing data to be encrypted into a storage device of an exemplary NAS, in accordance with an embodiment of the invention. At step 704, a user inputs a password using a device that is not part of the NAS. In one embodiment, the user inputs the password by way of a user interface. The user interface may comprise a graphical user interface, in which the user types in the appropriate password using his keyboard. In one or more other embodiments, the user may transmit the password using any portable storage device or portable media, such as a floppy disk or USB drive, that is capable of providing the password. At step 708, the password is hashed using a hashing algorithm, such as an MD5 hashing algorithm, to generate one or more digest(s). In one embodiment, the digest(s) comprise a 128-bit value used as an encryption key by the data encryption/decryption circuitry. In another embodiment, two 128-bit preliminary digests may be generated and concatenated to form a 256-bit digest. Each of the two 128-bit digests may be unique, since a different hashing (or hash) key may be used to generate each of the two 128-bit digests. The hashing key may be stored in a device such as a random access memory, such as that pictured in FIG. 2. In other embodiments, more than two preliminary digests may be concatenated to generate a longer digest. At step 712, the digest is verified using a predetermined value. At step 716, a comparison is made between the digest and the predetermined value. If the digest equals the predetermined value, the process continues with step 720, at which the digest is used as the encryption key by the encryption/decryption circuitry, in encrypting or decrypting data written to or read from a data storage device (e.g., the NAS). Otherwise, at step 724, the user is prompted to input the password again. The encryption or decryption process may remain at step 724 until the user provides the correct password.

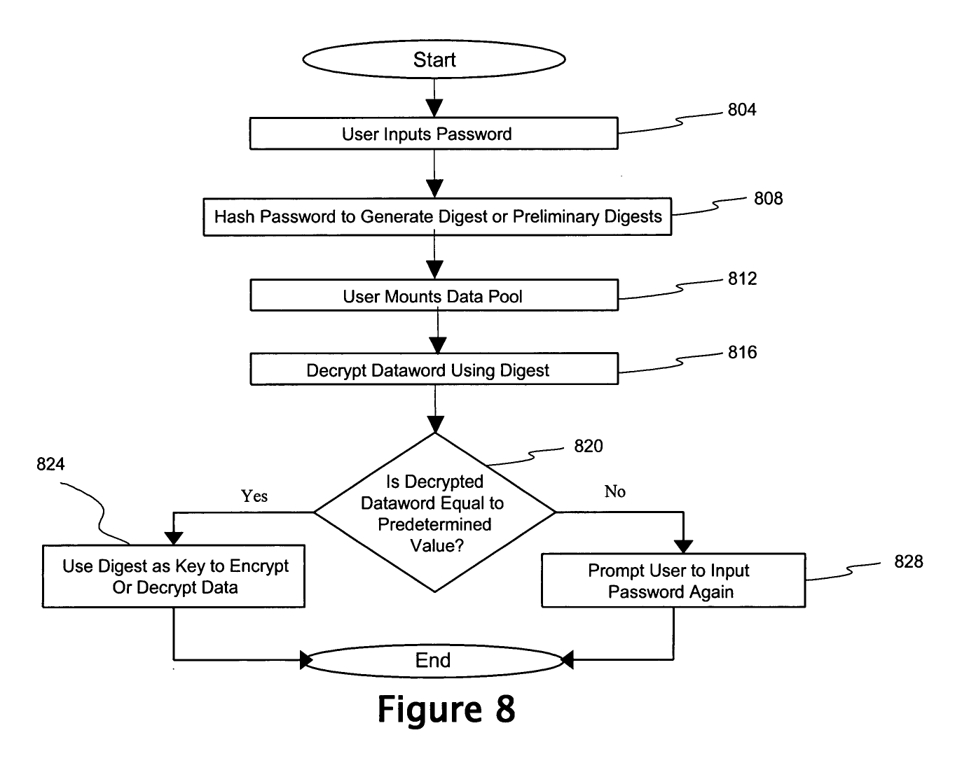

FIG. 8 is an operational flow diagram illustrating a generation of an encryption key or digest used by a data encryption/decryption circuitry or hardware, allowing data to be encrypted into a storage device of an exemplary NAS, in accordance with an embodiment of the invention. At step 804, a user may input a password using an external device, such as any portable device, that is not part of the NAS, as was previously discussed. In one or more other embodiments, the user may transmit the password using any portable storage device or portable media, such as a floppy disk or USB drive, that is capable of providing the password. In one embodiment, the user inputs the password by way of a user interface. The user interface may comprise a graphical user interface, in which the user types in the appropriate password using his keyboard. At step 808, the password is hashed using a hashing algorithm, such as an MD5 hashing algorithm, to generate one or more digests. In one embodiment, the digest(s) comprise a 128-bit value used as an encryption key by the data encryption/decryption circuitry. In another embodiment, two 128-bit preliminary digests may be generated and concatenated to form a 256-bit digest. Each of the two 128-bit digests may be unique, since a different hashing key may be used to generate each of the two 128-bit digests. The hashing key may be stored in a device such as a random access memory. In other embodiments, more than two preliminary digests may be concatenated to generate a longer digest. At step 812, the user mounts one or more data pools residing within the one or more storage devices in the NAS. At step 816, a particular dataword residing within a data pool of the one or more data pools is decrypted using the digest. At step 820, the decrypted dataword is compared to a predetermined value. If the decrypted dataword is equal to the predetermined value, then the process proceeds with step 824, at which the digest is used to decrypt or encrypt data stored in the storage device of the exemplary NAS. Otherwise, if the decrypted dataword is incorrect, the process continues at step 828. In this instance, the user-supplied password is incorrect, since the password is used to generate the digest. Hence, the user is prompted to input the password again. The encryption or decryption process may remain at step 828 until the user provides the correct password.

Aspects of the invention provide for a user interface (UI) that allows a user to input one or more passwords, allowing encrypted data to be stored in the one or more data storage devices. If the user desires data to be encrypted, a password must be input using a field of the UI. In one embodiment, the user may input two passwords, using two input fields provided by the UI. In one embodiment, the UI may provide two fields, so that a user may input the same password twice, facilitating a way of verifying the password input by the user. The UI may provide an indicator on the UI that indicates that data, such as a data pool is encrypted. In one embodiment, the NAS mounts non-encrypted data pools prior to mounting any encrypted data pools.

While the invention has been described with reference to certain embodiments, it will be understood by those skilled in the art that various changes may be made and equivalents may be substituted without departing from the scope of the invention. In addition, many modifications may be made to adapt a particular situation or material to the teachings of the invention without departing from its scope. Therefore, it is intended that the invention not be limited to the particular embodiment disclosed, but that the invention will include all embodiments falling within the scope of the appended claims.

1. A method of preventing unauthorized use of data that is stored in one or more data storage devices comprising:
executing a software that generates one or more device drivers; and
utilizing said one or more device drivers to encrypt said data.

2. The method of claim 1 wherein said software comprises a Linux loadable module.

3. The method of claim 1 wherein said executing is performed using a Linux operating system.

4. The method of claim 1 wherein said one or more device drivers is used to store said encrypted data into said one or more storage devices.

5. The method of claim 1 wherein said one or more device drivers is used to store said encrypted data for up to 256 data storage devices.

6. The method of claim 1 wherein said data comprises metadata.

7. A method of storing encrypted data into one or more data storage devices comprising:
generating a first signal from a file system;
transmitting said first signal to a first device driver;
generating a second signal from said first device driver after receiving said first signal;
transmitting said second signal to a second device driver;
encrypting said data to generate encrypted data, said second signal causing encryption of said data;
storing said encrypted data into a buffer;
generating a third signal to said first device driver that indicates encryption has been performed;
generating a fourth signal to a third device driver from said first device driver; and
writing said encrypted data from said buffer into said one or more data storage devices, said third signal causing said writing of said encrypted data into said one or more data storage devices.

8. The method of claim 7 wherein said encrypting is performed by way of providing a key to an encryption circuitry.

9. The method of claim 8 wherein said key is generated using a codeword.

10. The method of claim 9 wherein said codeword comprises 255 characters.

11. The method of claim 9 wherein said key comprises 128 bits.

12. The method of claim 9 wherein said key comprises 256 bits.

13. The method of claim 9 wherein said key is generated using a hash key operating on a hash function.

14. The method of claim 9 wherein said key comprises 256 bits, said key generated using two hash keys operating on a hash function that uses said codeword, each of said two hash keys generating a corresponding and unique 128-bit preliminary digest, said two unique 128 bit preliminary digests concatenated together to form said 256-bit key.

15. The method of claim 9 wherein said codeword is provided by a user inputting said codeword using a user interface.

16. The method of claim 14 wherein said hash function comprises an MD5 hashing function.

17. The method of claim 7 wherein said one or more data storage devices comprises up to 256 data storage devices.

18. The method of claim 7 further comprising reading and decrypting said encrypted data stored in said one or more data storage devices.

19. The method of claim 18 wherein said decrypting is performed using a key.

20. The method of claim 19 wherein said key is generated using a codeword.

21. The method of claim 19 wherein said key is generated using a hashing function.

22. The method of claim 19 wherein said key comprises 128 bits.

23. The method of claim 19 wherein said key comprises 256 bits.

24. The method of claim 18 wherein said reading and decrypting said encrypted data comprises:
generating a fifth signal from said file system;
transmitting said fifth signal to said first device driver;
generating a sixth signal from said first device driver;
transmitting said sixth signal to said third device driver from said first device driver;
reading data stored in said one or more data storage devices, said sixth signal causing said reading of said encrypted data from said one or more data storage devices;
generating a seventh signal from said third device driver to said first device driver indicating that said encrypted data is read from said one or more data storage devices;
transmitting said seventh signal to said first device driver from said third device driver; and
generating an eighth signal from said first device driver to said second device driver, said eighth signal causing decryption of said encrypted data from said one or more data storage devices.

25. A system for securely storing encrypted data using one or more data storage devices comprising:
one or more memories;
a software resident in said one or more memories; and
a processor executing said software resident in said one or more memories, said executing generating one or more device drivers, said one or more device drivers generating encrypted data from said data, said encrypted data being stored in said one or more data storage devices.

26. The system of claim 25 wherein said data comprises metadata.

27. The system of claim 25 wherein said software resident in said one or more memories is compiled by executing a Linux loadable module stored in said one or more memories.

28. The system of claim 25 wherein said one or more memories comprises one or more random access memories.

29. The system of claim 25 wherein said one or more memories comprises one or more non-volatile memories.

30. The system of claim 25 wherein said one or more memories comprises one or more flash memories.
